(19) United States
(12) Patent Application Publication
(10) Pub. No.: US 2013/0208427 A1
(43) Pub. Date: Aug. 15, 2013

(54) GROUNDING MECHANISM FOR HEAT SINK ASSEMBLY

(71) Applicants: MENG-HSIEN LIN, Tu-Cheng (TW); YAO-TING CHANG, Tu-Cheng (TW)

(72) Inventors: MENG-HSIEN LIN, Tu-Cheng (TW); YAO-TING CHANG, Tu-Cheng (TW)

(73) Assignee: HON HAI PRECISION INDUSTRY CO., LTD., Tu-Cheng (TW)

(21) Appl. No.: 13/457,709

(22) Filed: Apr. 27, 2012

(30) Foreign Application Priority Data
Feb. 15, 2012 (TW) 101104881

(51) Int. Cl. H05K 7/20

(52) U.S. Cl. 361/720

(57) ABSTRACT

A ground mechanism for a heat sink is attached to a circuit board. The ground mechanism includes a first latching member, a second latching member, a conductive member, and an elastic member. The first latching member and a second latching member latch the heat sink on the circuit board. The conductive member is formed on the circuit board. The elastic member is sandwiched between the first latching member and the heat sink. The elastic member electrically connects the first latching member to the heat sink, and the second latching member electrically connect the first latching member to the conductive member to conduct electromagnetic charges from the heat sink to a grounding pin of the circuit board.

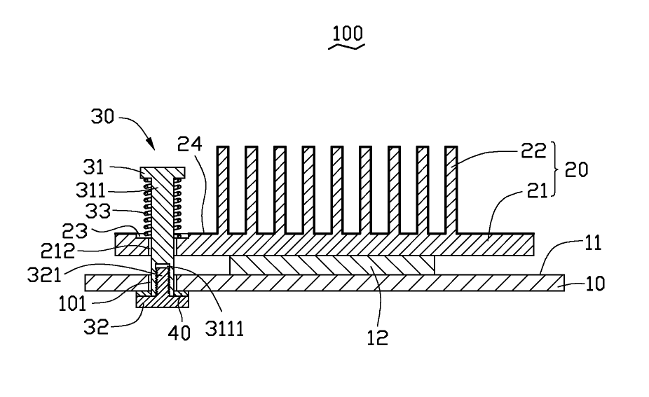

### BACKGROUND

1. Technical Field

The disclosure generally relates to heat sink assemblies, and particularly to a grounding mechanism used in a heat sink assembly.

2. Description of Related Art

Heat sinks are usually positioned on electrical components which generate more heat. In order to prevent electrostatic charges on the heat sinks from damaging the electrical components, a grounding mechanism is usually provided for the removal of electrostatic charges from the heat sink.

However, a typical grounding mechanism of the heat sink complicates the assembly process. In addition, surfaces of current heat sink usually need to form a non-conductive layer for improving dissipating effects. Such non-conductive layer prevents the grounding mechanism from being grounded.

Therefore, there is room for improvement within the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the exemplary grounding mechanism. Moreover, in the drawings, like reference numerals designate corresponding parts throughout the several views. Wherever possible, the same reference numbers are used throughout the drawings to refer to the same or like elements of an embodiment.

FIGURE is a schematic view of an exemplary embodiment of a grounding mechanism of a heat sink assembly.

### DETAILED DESCRIPTION

Referring to the FIGURE, a heat assembly 100 is attached to a printed circuit board 10 in an exemplary embodiment. The heat assembly 100 includes a heat sink 20, a latching module 30, and a conductive member 40. A chip 12 is mounted on one surface 11 of the printed circuit board 10. The printed circuit board 10 defines an aperture 101.

The heat sink 20 is made of metal, and includes a main portion 21 and a number of fins 22. The fins 22 protrude from the main portion 21. The heat sink 20 has a non-conductive layer 24 formed by anode treatment. One portion of the main portion 21 is cut to define a groove 23 and a through hole 212 communicating with each other. In this exemplary embodiment, the groove 23 is cut by laser to remove one part of the non-conductive layer 24 for allowing the latching module 30 to be electrically connected to the heat sink 20.

The latching module 30 includes a first latching member 31, a second latching member 32, and an elastic member 33. The latching module 30 is made of metal. In this exemplary embodiment, the first latching member 31 includes a shank 311. The elastic member 33 is fitted around the shank 311. A distal end of the shank 311 defines a threaded hole 3111. The second latching member 32 includes a threaded portion 321 engaging with the threaded hole 3111 for latching the second latching member 32 on the first latching member 31. The conductive member 40 can be made of copper or tin. The conductive member 40 is ring-shaped, and is mounted on another surface of the printed circuit board 10 opposite to the surface 11. The conductive member 40 is electrically connected to the printed circuit board 10.

To assemble the heat sink 20 to the printed circuit board 10, the main portion 21 is mounted on the chip 12. The through hole 212 is aligned with the aperture 101 of the printed circuit board 10. The elastic member 33 is fitted around the shank 311 of the first latching member 31. A distal end of the shank 311 passes through the groove 23, the through hole 212, and the aperture 101 of the printed circuit board 10. The conductive member 40 is fitted around the shank 311, and the second latching member 32 is threadedly engaged with the threaded hole 3111 for latching together. One end of the elastic member 33 elastically abuts in the groove 23, and the other end of the elastic member 33 abuts against the first latching member 31. Thus, the elastic member 33 is electrically connected to the heat sink 20. The second latching member 32 further electrically connects the first latching member 31 to the conductive member 40. Thus, the heat sink 20 is electrically connected to the circuit board 10.

A significant advantage of the grounding mechanism is that the latching module 30 is easily assembled to the heat sink 20 and the printed circuit board 10. This simplifies the assembly of heat sink assembly 100, and effectively reduces cost.

It is to be understood, however, that even through numerous characteristics and advantages of the disclosure have been set forth in the foregoing description, together with details of the system and function of the disclosure, the disclosure is illustrative only, and changes may be made in detail, especially in the matters of shape, size, and arrangement of parts within the principles of the disclosure to the full extent indicated by the broad general meaning of the terms in which the appended claims are expressed.

What is claimed is:

1. A ground mechanism for a heat sink attached to a circuit board, the ground mechanism comprising:
a first latching member and a second latching member latching the heat sink on the circuit board;
a conductive member formed on the circuit board;
an elastic member sandwiched between the first latching member and the heat sink;
wherein the elastic member electrically connects the first latching member to the heat sink, the second latching member electrically connect the first latching member to the conductive member to conduct electromagnetic charges from the heat sink to the circuit board.

2. The ground mechanism as claimed in claim 1, wherein the heat sink includes a non-conductive layer, and defines a groove and a through hole, the groove is formed by removing one part of the non-conductive layer for allowing the latching module to be electrically connected to the heat sink.

3. The ground mechanism as claimed in claim 2, wherein the heat sink includes a main portion and a number of fins protruding from the main portion, the non-conductive layer formed by an anode treatment.

4. The ground mechanism as claimed in claim 1, wherein the first latching member includes a shank, the elastic member is fitted around the shank.

5. The ground mechanism as claimed in claim 4, wherein a distal end of the shank defines a threaded hole, the second latching member includes a threaded portion engaging into the threaded hole.

6. A heat sink assembly comprising:
a heat sink;
a circuit board;
a ground mechanism comprising:
a first latching member and a second latching member latching the heat sink on the circuit board;
a conductive member formed on the circuit board;
an elastic member sandwiched between the first latching member and the heat sink;
wherein the elastic member electrically connects the first latching member to the heat sink, the second latching member electrically connect the first latching member to the conductive member to conduct electromagnetic charges from the heat sink to the circuit board.

7. The heat sink assembly as claimed in claim 6, wherein the first latching member includes a shank, and the elastic member is fitted around the shank.

8. The heat sink assembly as claimed in claim 7, wherein a distal end of the shank defines a threaded hole, the second latching member includes a threaded portion engaging into the threaded hole.
